(19) United States
(12) Patent Application Publication
(10) Pub. No.: US 2025/0311209 A1
(43) Pub. Date: Oct. 2, 2025

(54) SEMICONDUCTOR STRUCTURE FOR 3D MEMORY AND MANUFACTURING METHOD THEREOF

(71) Applicant: MACRONIX International Co., Ltd., Hsinchu (TW)

(72) Inventor: Yan-Ru Su, Chiayi County (TW)

(73) Assignee: MACRONIX International Co., Ltd., Hsinchu (TW)

(21) Appl. No.: 18/617,852

(22) Filed: Mar. 27, 2024

(51) Int. Cl. H10B 41/27; H10B 41/42

(52) U.S. Cl. CPC H10B 41/27; H10B 41/42

(57) ABSTRACT

Provided are a semiconductor structure which may be used in a 3D AND flash memory and a manufacturing method thereof. The semiconductor structure includes a substrate having a memory device region including memory array and staircase regions and a peripheral region, a circuit structure layer and a first conductive layer sequentially on the circuit structure layer, a stacked structure including second conductive layers and insulating layers and having a staircase profile on the first conductive layer in the memory device region, an oxide layer on the first conductive layer, an insulating wall in the oxide layer, and dummy pillars in the peripheral and staircase regions. The insulating wall penetrates the first conductive layer and surrounds the stacked structure. Each dummy pillar in the peripheral region penetrates the oxide layer and the first conductive layer. Each dummy pillar in the staircase region penetrates the stacked structure and the first conductive layer.

### BACKGROUND

### Technical Field

The present invention relates to a semiconductor structure and a manufacturing method thereof, and in particular, to a semiconductor structure for a three-dimensional (3D) memory and a manufacturing method thereof.

### Description of Related Art

Non-volatile memory, such as flash memory, has become a type of memory widely used in personal computers and other electronic devices because it has the advantage that stored data will not disappear even after power is turned off. With the development of process technology, circuit design and program design algorithms, the size of memory devices has been greatly reduced in order to achieve higher integration.

However, due to the process limitations, the size of a traditional planar memory device has been unable to meet the demand for size reduction. Therefore, the current development of the 3D flash memory device has made the type of the memory device develop from a 2D memory device with the planar gate structure to the 3D memory device with the vertical channel (VC) structure.

In the current 3D flash memory device process, after the thermal treatment, the hydrogen contained in the nitride layer in the peripheral region may cause the threshold voltage (Vt) shifting problem in the P-type metal-oxide-semiconductor (PMOS) transistor.

Therefore, as the size of electronic devices continues to shrink and users' requirements for the performance of electronic devices continue to increase, those skilled in the art continue to improve the size and performance of the memory device used in electronic devices.

### SUMMARY

The present invention provides a semiconductor structure for a 3D memory and a manufacturing method thereof, wherein the nitride layer in the peripheral region surrounding the memory device region is removed to solve the problem of the threshold voltage shifting in the PMOS transistor caused by the nitride layer after the thermal treatment.

The semiconductor structure for a 3D memory of the present invention includes a substrate, a circuit structure layer, a first conductive layer, a stacked structure, an oxide layer, a first insulating wall and a plurality of first dummy pillars. The substrate has a memory device region and a peripheral region surrounding the memory device region, and the memory device region includes a memory array region and a staircase region. The circuit structure layer is disposed on the substrate. The first conductive layer is disposed on the circuit structure layer. The stacked structure is disposed on the first conductive layer in the memory device region, includes a plurality of second conductive layers and a plurality of insulating layers alternately stacked, and has a staircase profile in the staircase region has a staircase profile. The oxide layer is disposed on the first conductive layer and surrounds the stacked structure. The first insulating wall is disposed in the oxide layer, penetrates through the first conductive layer, and surrounds the stacked structure. The plurality of first dummy pillars are disposed in the peripheral region and the staircase region, wherein each first dummy pillar in the peripheral region penetrates through the oxide layer and the first conductive layer, and each first dummy pillar in the staircase region penetrates through the stacked structure and the first conductive layer.

In an embodiment of the semiconductor structure of the present invention, the semiconductor structure further includes a plurality of supporting pillars disposed in the staircase region, and penetrating through the stacked structure and the first conductive layer.

In an embodiment of the semiconductor structure of the present invention, the semiconductor structure further includes a plurality of second insulating walls parallel to each other disposed in the stacked structure to divide the stacked structure into a plurality of blocks arranged parallel to each other.

In an embodiment of the semiconductor structure of the present invention, in each of the blocks, the first dummy pillars are located at a first side of the memory array region, and the supporting pillars are located at a second side opposite to the first side of the memory array region.

In an embodiment of the semiconductor structure of the present invention, the first dummy pillars in each of the blocks are adjacent to the supporting pillars in an adjacent block, and the supporting pillars in each of the blocks are adjacent to the first dummy pillars in an adjacent block.

In an embodiment of the semiconductor structure of the present invention, the semiconductor structure further includes a plurality of vertical channel structures disposed in the memory array region and penetrating through the stacked structure and the first conductive layer.

In an embodiment of the semiconductor structure of the present invention, the first insulating wall is located in the memory device region and adjacent to a boundary between the memory device region and the peripheral region, and spacing a distance from a lowermost second conductive layer in the stacked structure.

The manufacturing method of the semiconductor structure for a 3D memory of the present invention includes the following steps. A substrate is provided, wherein the substrate has a memory device region and a peripheral region surrounding the memory device region, and the memory device region comprises a memory array region and a staircase region. A circuit structure layer is formed on the substrate. A first conductive layer is formed on the circuit structure layer. A stacked structure is formed on the first conductive layer in the memory device region, wherein the stacked structure comprises a plurality of second conductive layers and a plurality of insulating layers alternately stacked and has a staircase profile in the staircase region. An oxide layer is formed on the first conductive layer, wherein the oxide layer surrounds the stacked structure. A first insulating wall is formed in the oxide layer, wherein the first insulating wall penetrates through the first conductive layer and surrounds the stacked structure. A plurality of first dummy pillars are formed in the peripheral region and the staircase region, wherein each first dummy pillar in the peripheral region penetrates through the oxide layer and the first conductive layer, and each first dummy pillar in the staircase region penetrates through the stacked structure and the first conductive layer.

In an embodiment of the manufacturing method of the present invention, a forming method of the stacked structure and the oxide layer the following steps. A first initial stacked structure is formed on the first conductive layer, wherein the first initial stacked structure comprises the plurality of insulating layers and a plurality of sacrificial layers alternately stacked. A part of the insulating layers and a part of the sacrificial layers are removed to expose the first conductive layer in the peripheral region and to form a second initial stacked structure in the memory device region, wherein the second initial stacked structure has the staircase profile in the staircase region. The oxide layer is formed on the first conductive layer. The plurality of sacrificial layers are replaced with the plurality of second conductive layers.

In an embodiment of the manufacturing method of the present invention, after forming the oxide layer and before replacing the plurality of sacrificial layers with the plurality of second conductive layers, the manufacturing method further includes forming a plurality of vertical channel structures in the memory array region, wherein each vertical channel structure penetrates through the second initial stacked structure and the first conductive layer.

In an embodiment of the manufacturing method of the present invention, after forming the plurality of vertical channel structures and before replacing the plurality of sacrificial layers with the plurality of second conductive layers, the manufacturing method further includes forming the plurality of first dummy pillars in the peripheral region and the staircase region, wherein each first dummy pillar in the peripheral region penetrates through the first conductive layer, and each first dummy pillar in the staircase region penetrates the oxide layer and the second initial stacked structure and the first conductive layer.

In an embodiment of the manufacturing method of the present invention, when forming the plurality of vertical channel structures, the manufacturing method further includes forming a plurality of supporting pillars in the staircase region, wherein each supporting pillar penetrates through the second initial stacked structure and the first conductive layer.

In an embodiment of the manufacturing method of the present invention, after forming the plurality of first dummy pillars, the manufacturing method further includes the following steps. A first slit in the oxide layer is formed, wherein the first slit penetrates through the oxide layer and the first conductive layer and surrounds the second initial stacked structure. A plurality of second slits parallel to each other are formed in the second initial stacked structure to divide the second initial stacked structure into a plurality of blocks arranged parallel to each other. The plurality of sacrificial layers are replaced with the plurality of second conductive layers. The first slit and the plurality of second slits are filled with an insulating material to form the first insulating wall in the first slit and a plurality of second insulating walls in the second slits.

In an embodiment of the manufacturing method of the present invention, after forming the oxide layer and before replacing the plurality of sacrificial layers with the plurality of second conductive layers, the manufacturing method further includes forming the plurality of first dummy pillars in the peripheral region and the staircase region, wherein each first dummy pillar in the staircase region penetrates through the second initial stacked structure and the first conductive layer.

In an embodiment of the manufacturing method of the present invention, after forming the plurality of first dummy pillars and before replacing the plurality of sacrificial layers with the plurality of second conductive layers, the manufacturing method further includes forming a plurality of vertical channel structures in the memory array region, wherein each vertical channel structure penetrates through the second initial stacked structure and the first conductive layer.

In an embodiment of the manufacturing method of the present invention, when forming the plurality of vertical channel structures, the manufacturing method further includes forming a plurality of supporting pillars in the staircase region, wherein each supporting pillar penetrates through the second initial stacked structure and the first conductive layer.

In an embodiment of the manufacturing method of the present invention, after forming the plurality of vertical channel structures, the manufacturing method further includes the following steps. A first slit is formed in the oxide layer, wherein the first slit penetrates through the first conductive layer and surrounds the second initial stacked structure. A plurality of second slits parallel to each other are formed in the second initial stacked structure to divide the second initial stacked structure into a plurality of blocks arranged parallel to each other. The plurality of sacrificial layers are replaced with the plurality of second conductive layers. The first slit and the plurality of second slits are filled with an insulating material to form the first insulating wall in the first slit and a plurality of second insulating walls in the second slits.

In an embodiment of the manufacturing method of the present invention, a forming method of the stacked structure, the oxide layer and the plurality of first dummy pillars comprises the following steps. A first initial stacked structure is formed on the circuit structure layer, wherein the initial stacked structure comprises the plurality of insulating layers and a plurality of sacrificial layers alternately stacked. A part of the insulating layers and a part of the sacrificial layers are removed to form a second initial stacked structure in the memory device region, wherein the second initial stacked structure has the staircase profile in the staircase region. A first oxide material layer is formed to cover the second initial stacked structure. The plurality of first dummy pillars are formed in the peripheral region and the staircase region, wherein each first dummy pillar in the peripheral region penetrates through the first initial stacked structure and the first conductive layer, and each first dummy pillar in the staircase region penetrates through the first oxide material layer, the second initial stacked structure and the first conductive layer. A plurality of holes are formed to penetrate through the first initial stacked structure and the first conductive layer in the peripheral region. The plurality of sacrificial layers in the peripheral region are replaced with a second oxide material layer through the plurality of holes to form the oxide layer. A plurality of second dummy pillars are formed in the plurality of holes. The plurality of sacrificial layers in the memory device region are replaced with the plurality of second conductive layer.

In an embodiment of the manufacturing method of the present invention, before forming the plurality of first dummy pillars, the manufacturing method further includes forming a plurality of vertical channel structures in the memory array region, wherein each vertical channel structure penetrates through the second initial stacked structure and the first conductive layer.

In an embodiment of the manufacturing method of the present invention, when forming the plurality of vertical channel structures, the manufacturing method further includes forming a plurality of supporting pillars in the staircase region, wherein each supporting pillar penetrates through the second initial stacked structure and the first conductive layer.

In an embodiment of the manufacturing method of the present invention, after forming the plurality of first dummy pillars and before forming the plurality of holes, the manufacturing method further includes forming a plurality of vertical channel structures in the memory array region, wherein each vertical channel structure penetrates through the second initial stacked structure and the first conductive layer.

In an embodiment of the manufacturing method of the present invention, when forming the plurality of vertical channel structures, the manufacturing method further includes forming a plurality of supporting pillars in the staircase region, wherein each supporting pillar penetrates through the second initial stacked structure and the first conductive layer.

In an embodiment of the manufacturing method of the present invention, after forming the plurality of second dummy pillars, the manufacturing method further includes the following steps. A first slit is formed in the oxide layer, wherein the first slit penetrates through the first conductive layer and surrounds the second initial stacked structure. A plurality of second slits parallel to each other are formed in the second initial stacked structure to divide the second initial stacked structure into a plurality of blocks arranged parallel to each other. The plurality of sacrificial layers are replaced with the plurality of second conductive layers. The first slit and the plurality of second slits are filled with an insulating material to form the first insulating wall in the first slit and a plurality of second insulating walls in the second slits.

In an embodiment of the manufacturing method of the present invention, the first insulating wall is located in the memory device region and adjacent to a boundary between the memory device region and the peripheral region, and spacing a distance from a lowermost second conductive layer in the stacked structure.

Based on the above, in the semiconductor structure for the 3D memory and the manufacturing method thereof of the present invention, the stacked nitride layers in the peripheral region surrounding the memory device region are removed, so that there is no stacked structure including the oxide layers and the nitride layers in the peripheral region. In this way, the threshold voltage shifting problem in the semiconductor device, especially the PMOS transistor, in the circuit structure layer caused by the nitride layer in the peripheral region after the thermal treatment may be effectively avoided.

### BRIEF DESCRIPTION OF THE DRAWINGS

FIGS. 1A to 1E are schematic cross-sectional views of the manufacturing process of the semiconductor structure for the 3D memory of the first embodiment of the present invention.

FIGS. 2A to 2E are schematic top views of the manufacturing process of the semiconductor structure for the 3D memory according to the first embodiment of the present invention, in which FIGS. 1A to 1E are illustrated according to the A-A cross-section line in FIGS. 2A to 2E.

FIGS. 3A and 3B are respectively modifications of the first dummy pillar in the first embodiment of the present invention.

FIGS. 4A and 4B are variations of the first insulating wall and the second insulating wall in the first embodiment of the present invention.

FIGS. 5A to 5E are schematic cross-sectional views of the manufacturing process of the semiconductor structure for the 3D memory according to the second embodiment of the present invention.

FIGS. 6A, 6B and 6C respectively variations of the second dummy pillar in the second embodiment of the present invention.

FIG. 7 is a circuit diagram of the 3D AND flash memory array including the semiconductor structure of present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

The terms used herein are used to merely describe exemplary embodiments and are not used to limit the present invention. In this case, unless indicated in the context specifically, otherwise the singular forms include the plural forms.

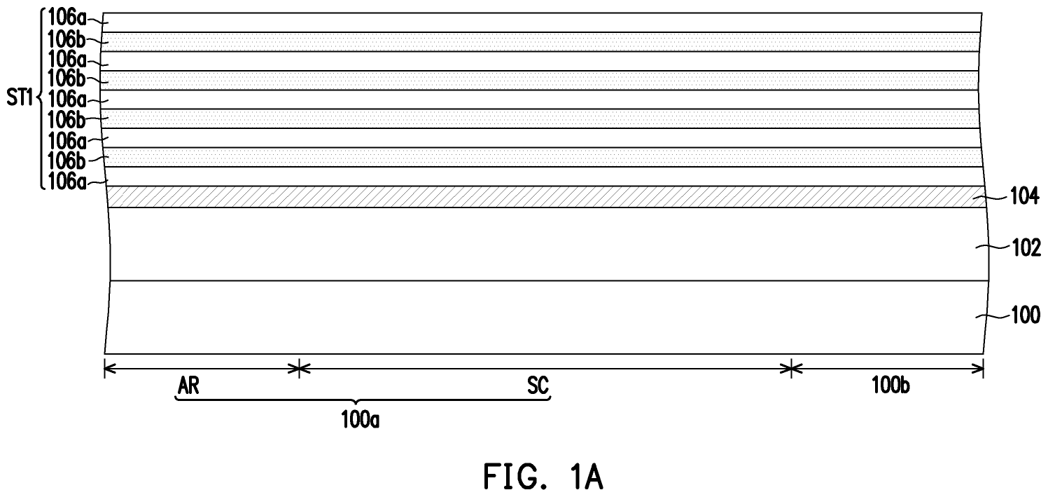

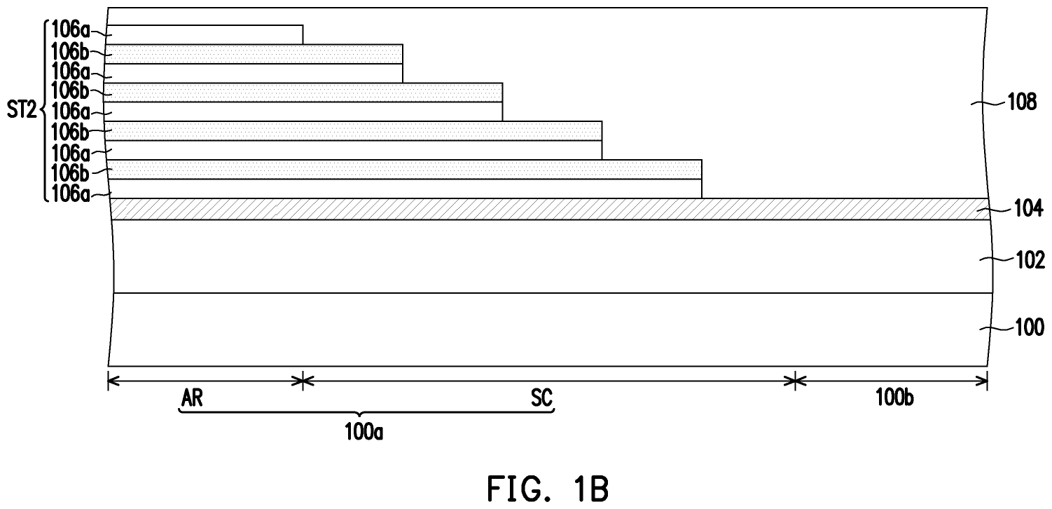

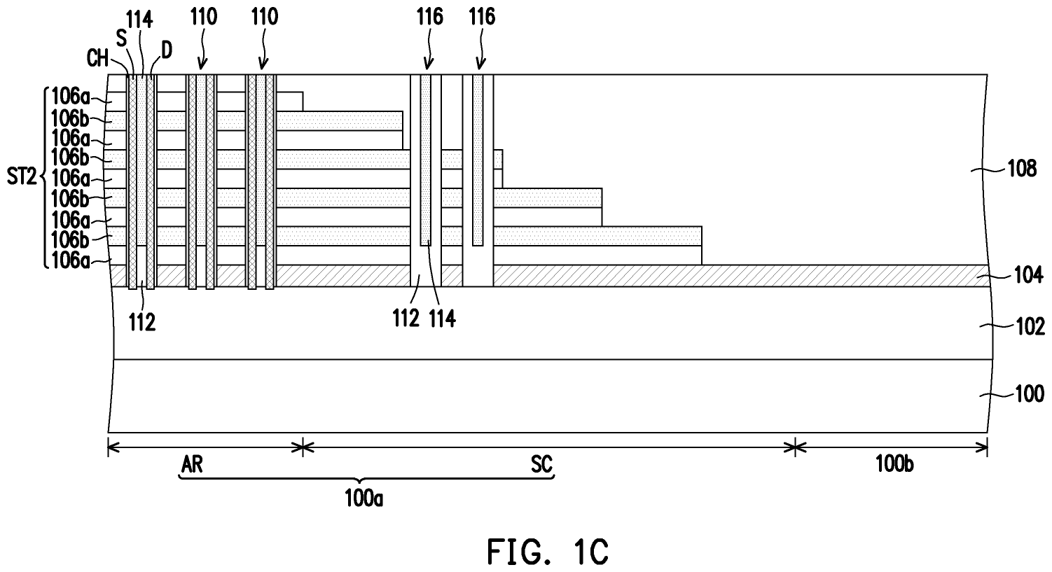

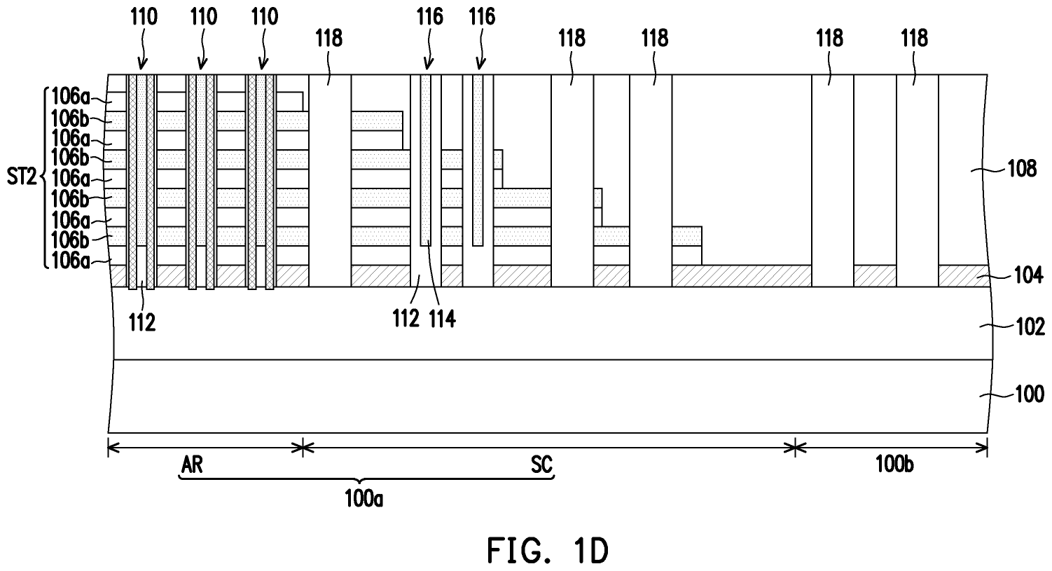

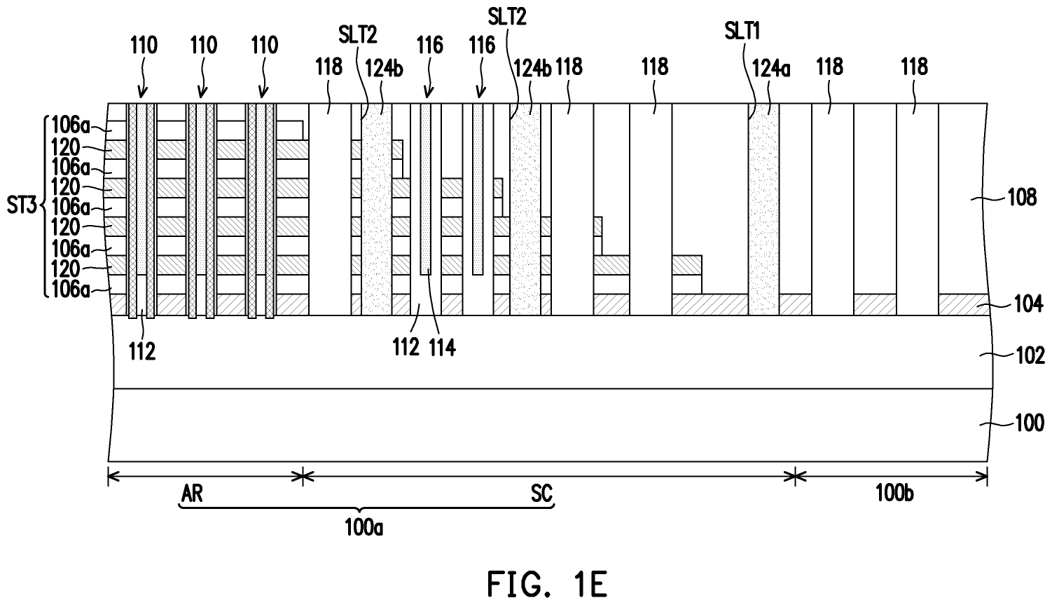

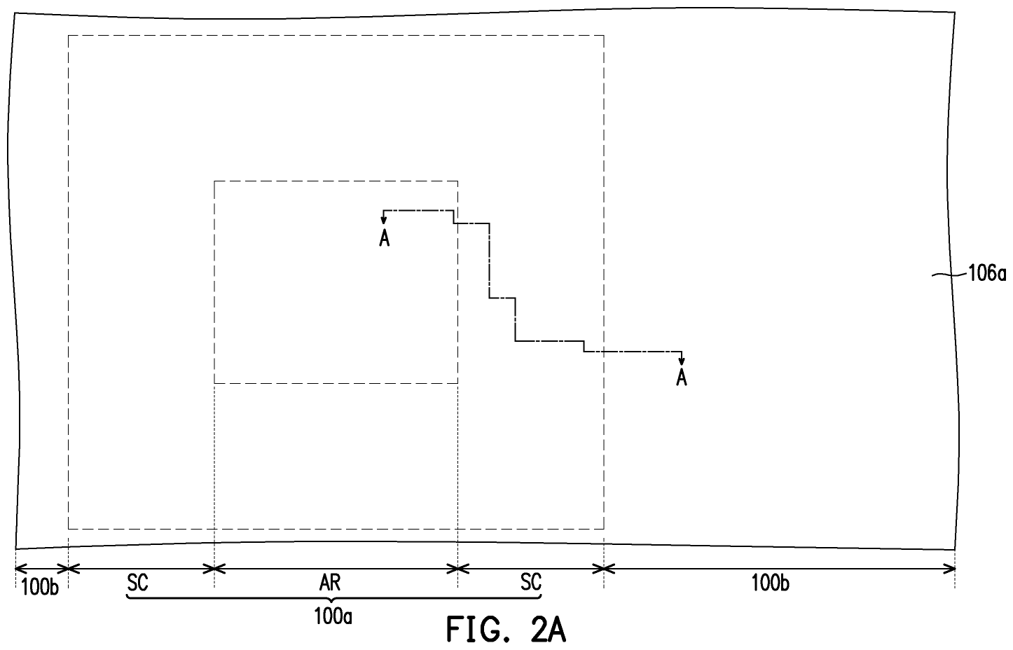

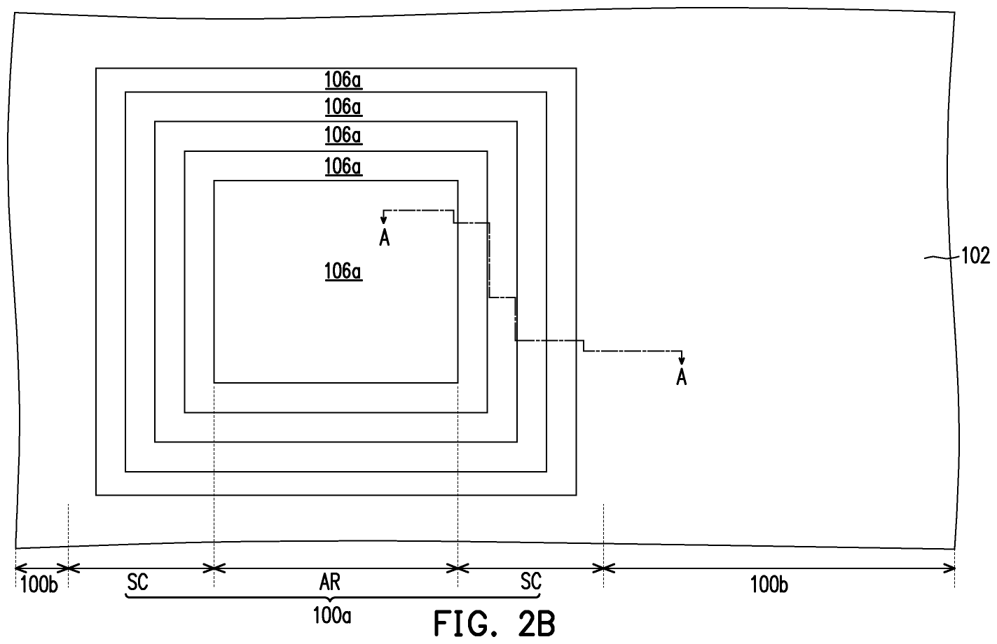

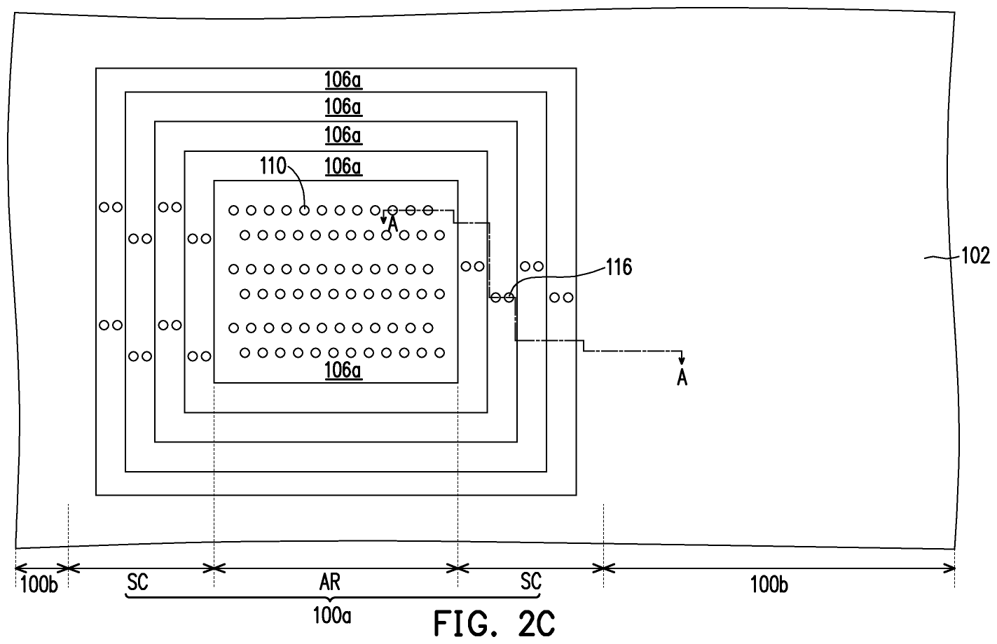

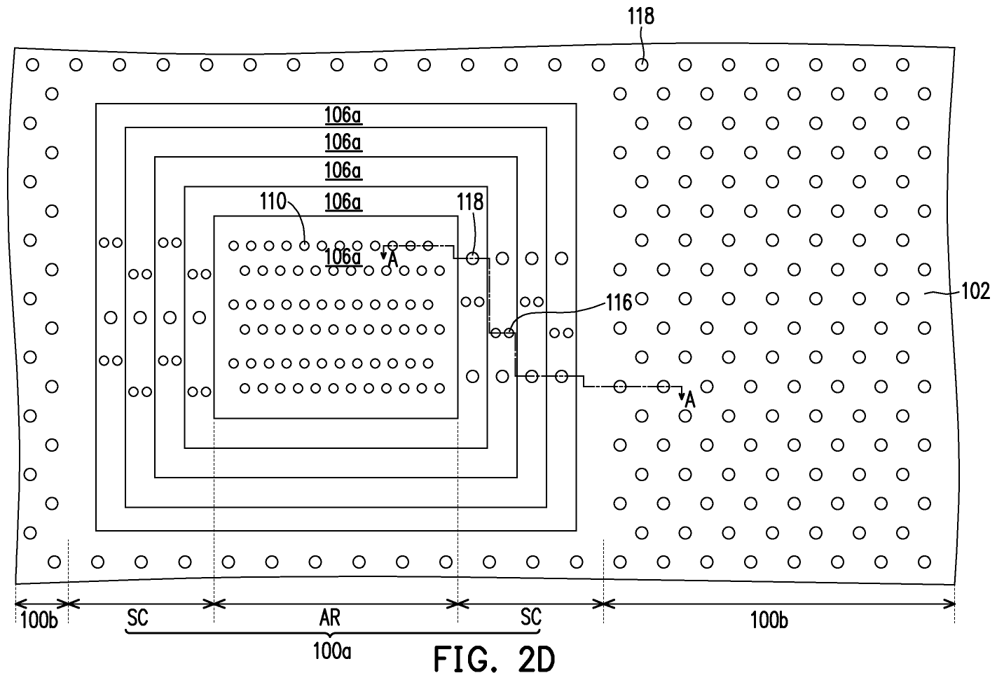

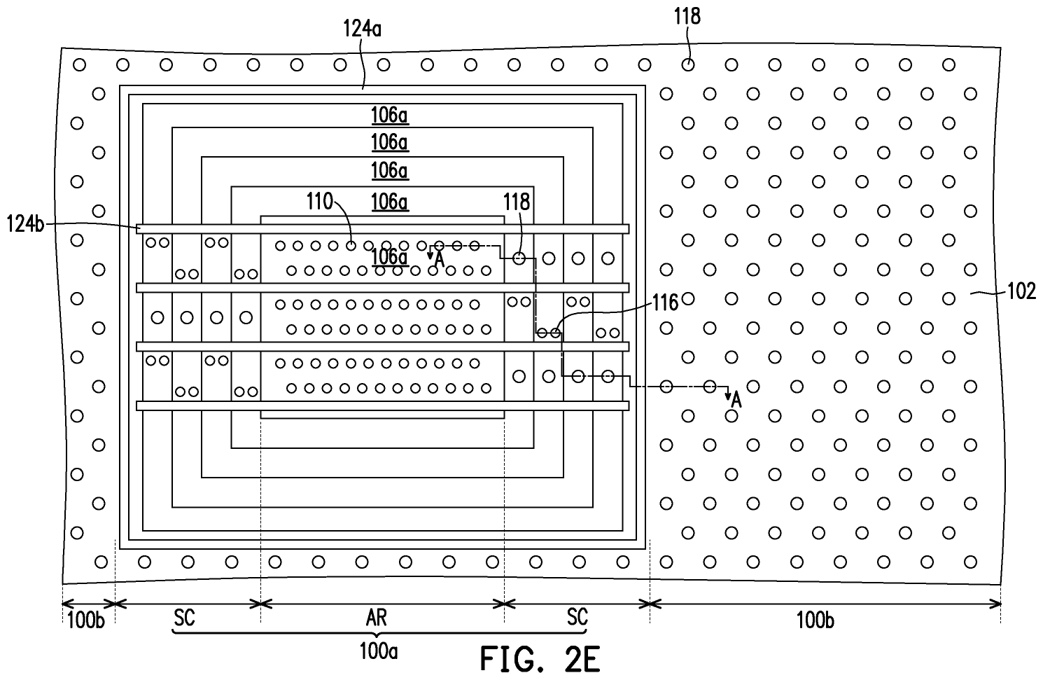

FIGS. 1A to 1E are schematic cross-sectional views of the manufacturing process of the semiconductor structure for the 3D memory of the first embodiment of the present invention. FIGS. 2A to 2E are schematic top views of the manufacturing process of the semiconductor structure for the 3D memory according to the first embodiment of the present invention, in which FIGS. 1A to 1E are illustrated according to the A-A cross-section line in FIGS. 2A to 2E.

Referring to FIGS. 1A and 2A, a substrate 100 is provided. In the present embodiment, the substrate 100 has a memory device region 100a and a peripheral region 100b surrounding the memory device region 100a. In addition, in the present embodiment, the memory device region 100a includes a memory array region AR and a staircase region SC. In the present embodiment, the substrate 100 may be a silicon substrate. As shown in FIG. 2A, from a top view of the substrate 100, the peripheral region 100b surrounds the memory device region 100a, and in the memory device region 100a, the staircase region SC surrounds the memory array region AR.

Then, a circuit structure layer 102 is formed on the substrate 100. The circuit structure layer 102 may include various commonly known semiconductor devices. For example, the circuit structure layer 102 may include a transistor formed at the surface of the substrate 100, an interconnect structure electrically connected to the transistor, and an inter-layer dielectric (ILD) layer covering the transistor and the interconnect structure, but the present invention is not limited thereto. In addition, in order to make the drawing clear and since the detailed configuration of the circuit structure layer 102 is well known to those skilled in the art, the detailed configuration of the circuit structure layer 102 is not shown in the drawing.

Then, a first conductive layer 104 is formed on the circuit structure layer 102. In the present embodiment, the first conductive layer 104 may be a ground layer and may be electrically connected to the circuit structure layer 102 through a conductive via, but the present invention is not limited thereto. The first conductive layer 104 may be a polysilicon layer, but the present invention is not limited thereto. In addition, a dielectric layer (not shown) may be formed between the first conductive layer 104 and the circuit structure layer 102. Depending on the actual situation, the first conductive layer 104 may be omitted in other embodiments.

After that, a first initial stacked structure ST1 is formed on the first conductive layer 104. The first initial stacked structure ST1 includes a plurality of insulating layers 106a and a plurality of sacrificial layers 106b alternately stacked. In the present embodiment, in the first initial stacked structure ST1, each of the lowermost layer and the uppermost layer is the insulating layer 106a, but the present invention is not limited thereto. In addition, in FIG. 1A, the numbers and thicknesses of the insulating layers 106a and the sacrificial layers 106b are only exemplary, and the present invention does not limit this. In the present embodiment, the insulating layer 106a is a silicon oxide layer, and the sacrificial layer 106b is a silicon nitride layer, but the present invention is not limited thereto.

Referring to FIGS. 1B and 2B, a part of the insulating layers 106a and a part of the sacrificial layers 106b are removed to expose the first conductive layer 104 in the peripheral region 100b and adjacent to the boundary between the memory device region 100a and the peripheral region 100b in the memory device region 100a, and to form a second initial stacked structure ST2 in the memory device region 100a. In addition, after removing a part of the insulating layers 106a and a part of the sacrificial layers 106b, the formed second initial stacked structure ST2 has a staircase profile, that is, the second initial stacked structure ST2 has a plurality of steps in the staircase region SC. A method of forming the second initial stacked structure ST2 to have a staircase profile is well known to those skilled in the art and will not be described further here.

Afterwards, an oxide layer 108 is formed on the substrate 100 to cover the exposed first conductive layer 104 and the second initial stacked structure ST2 in the memory device region 100a. In FIG. 2B, the first conductive layer 104, the sacrificial layers 106b and the oxide layer 108 are omitted to make the diagram clear and easy to understand. In the present embodiment, the oxide layer 108 is a silicon oxide layer. The oxide layer 108 is formed by, for example, forming an oxide material layer on the substrate 100 and then performing a planarization process so that the formed oxide layer 108 has a planar top surface. The planarization process is, for example, a chemical mechanical polishing (CMP) process.

As a result, in the peripheral region 100b, there is the oxide layer 108, but no nitride layer exists.

For the semiconductor structure of the present invention formed in this step, there is an oxide layer but not a nitride layer in the peripheral region 100b. Therefore, the subsequent thermal treatment(s) on the semiconductor structure of the present invention may not cause the threshold voltage shifting problem in the semiconductor device, especially the PMOS transistor, in the circuit structure layer 102.

Referring to FIGS. 1C and 2C, after the oxide layer 108 is formed, a plurality of vertical channel structures 110 are formed in the memory array region AR. The vertical channel structure 110 penetrates the oxide layer 108, the second initial stacked structure ST2 and the first conductive layer 104. In FIG. 2C, the first conductive layer 104, the sacrificial layer 106b and the oxide layer 108 are omitted to make the diagram clear and easy to understand.

In detail, in the present embodiment, in the memory array region AR, the vertical channel structure 110 extends downward from the top surface of the oxide layer 108 and penetrates through the oxide layer 108, the second initial stacked structure ST2 and the first conductive layer 104, and may include a channel layer CH, a source pillar S, a drain pillar D and a dielectric pillar that separates the source pillar S and the drain pillar from each other. In the present embodiment, the channel layer CH may be a polysilicon layer, and the material of the source pillar S and the drain pillar D may be metal or doped polysilicon. In addition, in the present embodiment, the dielectric pillar may include a dielectric layer 112 and a dielectric layer 114 located above the dielectric layer 112. The dielectric layer 112 may be an oxide layer, and the dielectric layer 114 may be a nitride layer. The forming methods of the channel layer CH, the source pillar S, the drain pillar D and the dielectric pillar are well known to those skilled in the art and will not be described further here.

In addition, in the present embodiment, when the vertical channel structure 110 is formed, a plurality of supporting pillars 116 may be formed in the staircase region SC at the same time. The supporting pillar 116 penetrates through the oxide layer 108, the second initial stacked structure ST2 and the first conductive layer 104.

In detail, in the present embodiment, in the staircase region SC, the supporting pillar 116 extends downward from the top surface of the oxide layer 108 and penetrates through the corresponding step portion(s) of the second initial stacked structure ST2 and the first conductive layer 104, and may include the dielectric layer 112 and the dielectric layer 114 located in the dielectric layer 112. The supporting pillar 116 may be used to provide support for the second initial stacked structure ST2 in the staircase region SC. The forming method of the supporting pillar 116 is well known to those skilled in the art and will not be described further here.

In FIG. 2C, the numbers and layout design of the vertical channel structures 110 and the supporting pillars 116 are only exemplary, and the present invention does not limit this.

Referring to FIGS. 1D and 2D, after forming the vertical channel structures 110 and the supporting pillars 116, a plurality of first dummy pillars 118 are formed in the peripheral region 100b and the staircase region SC. The first dummy pillar 118 in the peripheral region 1000b penetrates through the oxide layer 108 and the first conductive layer 104, and the first dummy pillar 118 in the staircase region 100b penetrates through the oxide layer 108, the second initial stacked structure ST2 and the first conductive layer 104. In FIG. 2D, the first conductive layer 104, the sacrificial layer 106b and the oxide layer 108 are omitted to make the diagram clear and easy to understand.

In detail, in the present embodiment, in the peripheral region 100b, the first dummy pillar 118 extends downward from the top surface of the oxide layer 108 and penetrates through the oxide layer 108 and the first conductive layer 104, and in the staircase region SC, the first dummy pillar 118 extends downward from the top surface of the oxide layer 108 and penetrates through the oxide layer 108, the corresponding step portion(s) of the second initial stacked structure ST2 and the first conductive layer 104. In the present embodiment, the material of the first dummy pillar 118 may be oxide. The first dummy pillar 118 located in the staircase region SC may be used to provide support for the second initial stacked structure ST2 in the staircase region SC. The forming method of the first dummy pillar 118 is well known to those skilled in the art and will not be described further here.

In the present embodiment, the first dummy pillar 118 is a pillar formed by oxide, but the present invention is not limited thereto. In other embodiments, the first dummy pillar 118 may have other configurations depending on the actual situation.

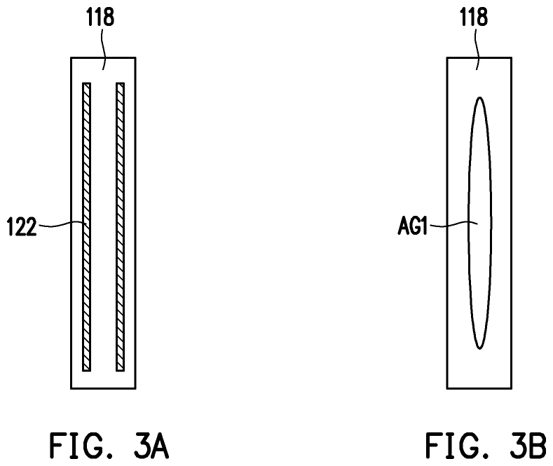

For example, as shown in FIG. 3A, a spacer layer 122 may be formed in the first dummy pillar 118 formed by oxide. The material of the spacer layer 122 may be polysilicon or nitride. In the present embodiment, when the material of the spacer layer 122 is nitride, since only a small amount of nitride is included in the first dummy pillar 118, the subsequent thermal treatment(s) on the semiconductor structure of the present invention may not cause the threshold voltage shifting problem in the semiconductor device, especially the PMOS transistor, in the circuit structure layer 102. Furthermore, in another embodiment, as shown in FIG. 3B, an air gap AG1 may be formed in the first dummy pillar 118.

In addition, in other embodiments, after the first dummy pillar 118 is formed, a conductive via may be formed in the first dummy pillar 118 depending on actual needs, which is well known to those skilled in the art and will not be described further here.

Referring to FIGS. 1E and 2E, after forming the first dummy pillar 118, a first slit SLT1 and a plurality of second slits SLT2 parallel to each other are formed in the oxide layer 108. In the present embodiment, the first slit SLT1 penetrates through the oxide layer 108 and the first conductive layer 104 and surrounds the second initial stacked structure ST2. In addition, the second slit SLT2 penetrates through the oxide layer 108, the second initial stacked structure ST2 and the first conductive layer 104 to divide the second initial stacked structure ST2 into a plurality of blocks arranged parallel to each other. The first slit SLT1 is not connected to the second slits SLT2. In FIG. 2E, the number of the blocks and the layout design are only exemplary, and the present invention does not limit these. In addition, in FIG. 2E, the first conductive layer 104, the sacrificial layer 106b and the oxide layer 108 are omitted to make the diagram clear and easy to understand.

In detail, in the present embodiment, the first slit SLT1 extends downward from the top surface of the oxide layer 108, penetrates through the oxide layer 108 and the first conductive layer 104, located in the memory device region 100a and adjacent to the boundary between the memory device region 100a and the peripheral region 100b, and spaces a distance from the lowermost sacrificial layer 106b in the second initial stacked structure ST2, but the present invention is not limited thereto. In other embodiments, the first slit SLT1 may be located in the peripheral region 100b and adjacent to the boundary between the memory device region 100a and the peripheral region 100b. Alternately, the first slit SLT1 may be located at the boundary between the memory device region 100a and the peripheral region 100b.

In the present embodiment, the second slit SLT2 extends downward from the top surface of the oxide layer 108 through the oxide layer 108, the second initial stacked structure ST2 and the first conductive layer 104, so as to divide the second initial stacked structure ST2 into a plurality of blocks arranged parallel to each other. In each block, the first dummy pillars 118 are located at a first side of the memory array region AR, and the supporting pillars 116 are located at a second side opposite to the first side of the memory array region AR. For example, as shown in FIG. 2E, in the blocks in the first and third rows, the first dummy pillars 118 are located at the right side of the memory array region AR and the supporting pillars 116 are located at the left side of the memory array region AR, and in the block in the second third row, the first dummy pillars 118 are located at the left side of the memory array region AR and the supporting pillars 116 are located at the right side of the memory array region AR, but the present invention is not limited thereto. In addition, the first dummy pillars 118 in each block are adjacent to the supporting pillars 116 in the adjacent block, and the supporting pillars 116 in each block are adjacent to the first dummy pillars 118 in the adjacent block. In other embodiments, depending on actual needs, the supporting pillars 116 and the first dummy pillars 118 may have other layout designs. Alternately, the second slits SLT2 may not be formed.

Then, after forming the first slit SLT1 and the second slits SLT2, through the first slit SLT1 and the second slits SLT2, a replacement process and a charge storage structure forming steps are performed to replace the sacrificial layers 106b in the second initial stacked structure ST2 with second conductive layers 120 and form a charge storage structure between the second conductive layers 120 and the channel layer CH. The replacement process and the charge storage structure forming steps are well known to those skilled in the art and will not be further described here.

As a result, a stacked structure ST3 consisting of the plurality of insulating layers 106a and the plurality of second conductive layers 120 alternately stacked is formed on the first conductive layer 104 in the memory device region 100a, and the stacked structure ST3 has the same staircase profile as the second initial stacked structure ST2. In addition, the formed stacked structure ST3 is surrounded by the oxide layer 108.

In FIG. 1E, the charge storage structure is not shown to make the diagram clear. The charge storage structure may be a composite structure composed of an oxide layer, a nitride layer and another oxide layer. When the semiconductor structure of the present embodiment is applied to a 3D memory, in the memory array region AR, the second conductive layers 120 may be used as the gates of the 3D memory, and in the staircase region SC, the second conductive layers 120 may be used as the word lines of the 3D memory.

After the replacement process and charge storage structure forming steps, an insulating material is filled in the first slit SLT1 and the second slits SLT2 to form a first insulating wall 124a in the first slit SLT1 and second insulating walls 124b in the second slits SLT2. That is, in the present embodiment, the first insulating wall 124a is formed in the oxide layer 108, penetrates through the oxide layer 108 and the first conductive layer 104 and surrounds the stacked structure ST3, and the first insulating wall 124a is located in the memory device region 100a and adjacent to the boundary between memory device region 100a and the peripheral region 100b and spaces a distance from the lowermost second conductive layer 120 in stacked structure ST3. In this way, a 3D memory including the semiconductor structure of the present invention is formed.

In the present embodiment, the material of the first insulating wall 124a and the second insulating walls 124b may be oxide or nitride, but the present invention is not limited thereto. In other embodiments, the first insulating wall 124a and the second insulating walls 124b may have other configurations depending on actual conditions.

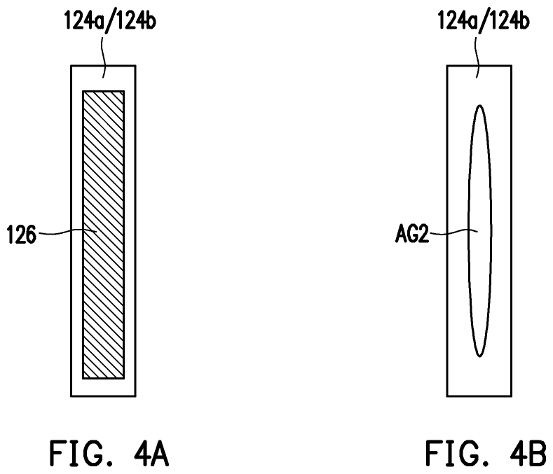

For example, as shown in FIG. 4A, a polysilicon layer 126 may be formed in the first insulating wall 124a and the second insulating walls 124b formed by oxide or nitride. When the material of the first insulating wall 124a and the second insulating walls 124b is nitride, since the first insulating wall 124a and the second insulating walls 124b are not large-sized devices, that is, there is no large amounts of nitride, the subsequent thermal treatment(s) on the semiconductor structure of the present invention may not cause the threshold voltage shifting problem in the semiconductor device, especially the PMOS transistor, in the circuit structure layer 102. Furthermore, in another embodiment, as shown in FIG. 4B, an air gap AG2 may be formed in the first insulating wall 124a and the second insulating walls 124b.

In the present embodiment, the first dummy pillars 118 are formed after the vertical channel structures 110 and the supporting pillars 116 are formed, but the present invention is not limited thereto. In other embodiments, the first dummy pillars 118 may be formed before the vertical channel structures 110 and supporting pillars 116 are formed. That is, after the oxide layer 108 in FIG. 1B is formed, the first dummy pillars 118 are formed in the peripheral region 100b and the staircase region SC, and after the first dummy pillars 118 are formed, the vertical channel structures 110 are formed in the memory array region AR and the supporting pillars 116 are formed in the staircase region SC. After that, the steps described in FIGS. 1E and 2E are performed.

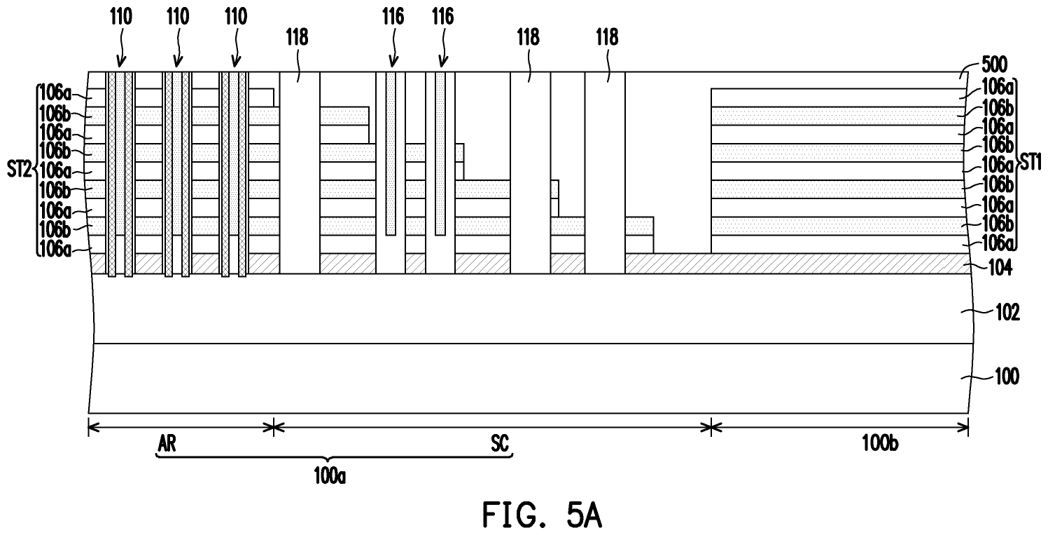

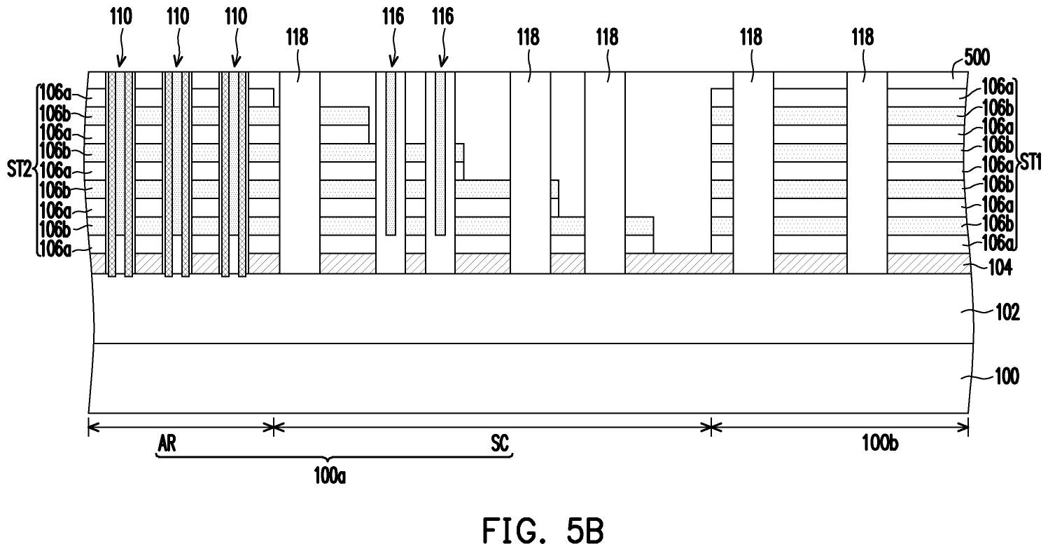

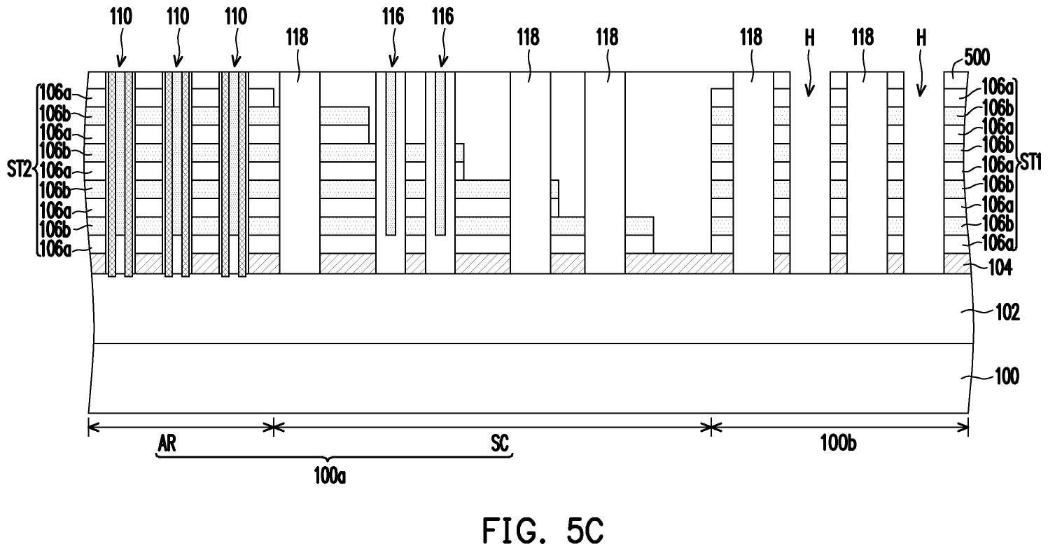

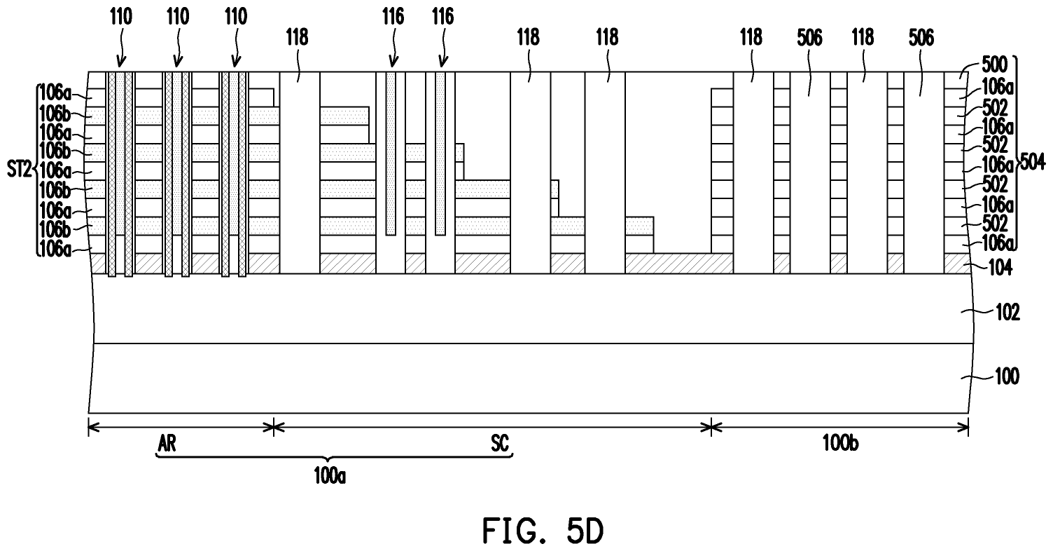

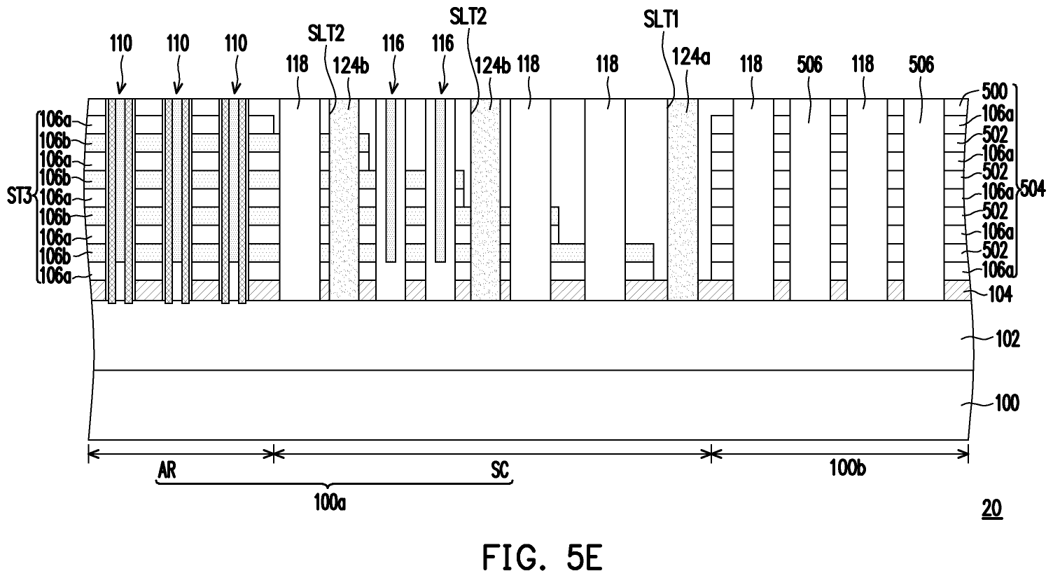

FIGS. 5A to 5E are schematic cross-sectional views of the manufacturing process of the semiconductor structure for the 3D memory according to the second embodiment of the present invention. In the present embodiment, devices that are the same as in the first embodiment will be represented by the same reference symbols and will not be described again.

Referring to FIG. 5A, after forming the first initial stacked structure ST1 in FIG. 1A, a part of the insulating layers 106a and a part of the sacrificial layers 106b are removed to form the second initial stacked structure ST2 in the memory device region 100a, and the first initial stacked structure ST1 in peripheral region 100b are remained. In addition, in the present embodiment, the first conductive layer 104 in the memory device region 100a and adjacent to the boundary between the memory device region 100a and the peripheral region 100b is exposed.

Then, a first oxide material layer 500 is formed on the substrate 100 to cover the second initial stacked structure ST2 in the memory device region 100a, the first initial stacked structure ST1 in the peripheral region 100b and the exposed first conductive layer 104. In the present embodiment, the first oxide material layer 500 is a silicon oxide layer. The first oxide material layer 500 is formed by, for example, forming an oxide material layer on the substrate 100 and then performing a planarization process so that the formed first oxide material layer 500 has a planar top surface. The planarization process is, for example, a chemical mechanical polishing process.

Referring to FIG. 5B, as described in FIG. 1C, after the first oxide material layer 500 is formed, a plurality of vertical channel structures 110 are formed in the memory array region AR, and a plurality of supporting pillars 116 is formed in the staircase region SC at the same time.

Then, after the vertical channel structures 110 and the supporting pillars 116 are formed, a plurality of first dummy pillars 118 are formed in the peripheral region 100b and the staircase region SC. In the present embodiment, in the peripheral region 100b, the first dummy pillar 118 penetrates through the first oxide material layer 500, the first initial stacked structure ST1 and the first conductive layer 104, and in the staircase region 100b, the first dummy pillar 118 penetrates through the first oxide material layer 500, the second initial stacked structure ST2 and the first conductive layer 104.

In detail, in the present embodiment, in the peripheral region 100b, the first dummy pillar 118 extends downward from the top surface of the first oxide material layer 500 and penetrates through the first oxide material layer 500, the first initial stacked structure ST1 and the first conductive layer 104, and in the staircase region SC, the first dummy pillar 118 extends downward from the top surface of the first oxide material layer 500 and penetrates through the first oxide material layer 500, the corresponding step portion(s) of the second initial stacked structure ST2 and the first conductive layer 104. The first dummy pillar 118 located in the peripheral region 100b may be used to provide support for the first initial stacked structure ST1 in the peripheral region 100b, and the first dummy pillar 118 located in the staircase region SC may be used to provide support for the second initial stacked structure ST2 in the staircase region SC.

Referring to FIG. 5C, a plurality of holes H penetrating through the first oxide material layer 500, the first initial stacked structure ST1 and the first conductive layer 104 are formed in the peripheral region 100b. In detail, in the present embodiment, the hole H extends downward from the top surface of the first oxide material layer 500 and penetrates through the first oxide material layer 500, the first initial stacked structure ST1 and the first conductive layer 104 to expose the sacrificial layers 106b of the first initial stacked structure ST1.

Referring to FIG. 5D, after the holes H are formed, a replacement process is performed through the holes H to replace the sacrificial layers 106b in the peripheral region 100b with the second oxide material layers 502. In this way, the first oxide material layer 500, the second oxide material layers 502 and the insulating layer 106a form an oxide layer 504 covering the first conductive layer 104 in the peripheral region 100b. After that, an oxide material is filled into the holes H to form second dummy pillars 506.

As a result, in the peripheral region 100b, there is the oxide layer 504 and the first dummy pillars 118 and the second dummy pillars 506 formed by the oxide material, but no nitride layer (sacrificial layers 106b) exists. That is, the stacked structure in the peripheral region 100b is composed of the stacked insulating layers 106a and second oxide material layer 502.

For the semiconductor structure of the present invention formed in this step, there is an oxide layer but not a nitride layer in the peripheral region 100b. Therefore, the subsequent thermal treatment(s) on the semiconductor structure of the present invention may not cause the threshold voltage shifting problem in the semiconductor device, especially the PMOS transistor, in the circuit structure layer 102.

In the present embodiment, the second dummy pillar 506 is a pillar formed by oxide, but the present invention is not limited thereto. In other embodiments, the second dummy pillar 506 may have other configurations depending on the actual situation.

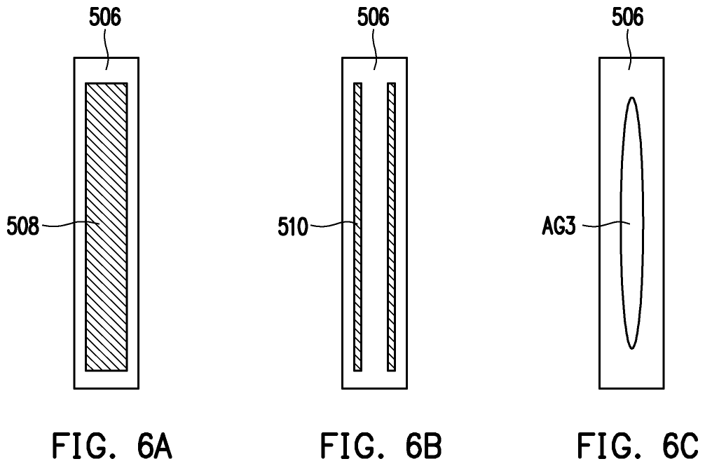

For example, as shown in FIG. 6A, a polysilicon layer 508 may be formed in the second dummy pillar 506 formed by oxide. Furthermore, in another embodiment, as shown in FIG. 6B, a spacer layer 510 may be formed in the second dummy pillar 506 formed by oxide. The material of the spacer layer 510 may be polysilicon or nitride. Additionally, in another embodiment, as shown in FIG. 6C, an air gap AG3 may be formed in the second dummy pillar 206.

Referring to FIG. 5E, after forming the second dummy pillars 206, a first slit SLT1 and a plurality of second slits SLT2 parallel to each other are formed in the first oxide material layer 500, and then a replacement process and a charge storage structure forming steps are performed to replace the sacrificial layers 106b in the second initial stacked structure ST2 with second conductive layers 120 and form a charge storage structure between the second conductive layers 120 and the channel layer CH.

As a result, a stacked structure ST3 consisting of the plurality of insulating layers 106a and the plurality of second conductive layers 120 alternately stacked is formed on the first conductive layer 104 in the memory device region 100a, and the stacked structure ST3 has the same staircase profile as the second initial stacked structure ST2. In addition, the formed stacked structure ST3 is surrounded by the oxide layer 504.

After the replacement process and charge storage structure forming steps, an insulating material is filled in the first slit SLT1 and the second slits SLT2 to form the first insulating wall 124a in the first slit SLT1 and the second insulating walls 124b in the second slits SLT2. In this way, a 3D memory including the semiconductor structure of the present invention is formed.

In the present embodiment, the first dummy pillars 118 are formed after the vertical channel structures 110 and the supporting pillars 116 are formed, but the present invention is not limited thereto. In other embodiments, the first dummy pillars 118 may be formed before the vertical channel structures 110 and supporting pillars 116 are formed. After that, the steps described in FIGS. 1E and 2E are performed to form a 3D memory including the semiconductor structure of the present invention.

To sum up, in the semiconductor structure for the 3D memory and the manufacturing method thereof of the present invention, the nitride layers in the initial stacked structure in the peripheral region surrounding the memory device region are removed, so that there is no stacked structure including the oxide layers and the nitride layers in the peripheral region. In this way, the threshold voltage shifting problem in the semiconductor device, especially the PMOS transistor, in the circuit structure layer caused by the nitride layer in the peripheral region after the thermal treatment may be effectively avoided.

In addition, even if nitride material, such as the nitride spacer layer, may exist in the device, such as the dummy pillar, in the peripheral region, since the nitride material only exists in a small amount, the subsequent thermal treatment(s) on the semiconductor structure of the present invention may not cause the threshold voltage shifting problem in the semiconductor device, especially the PMOS transistor, in the circuit structure layer 102.

Hereinafter, a circuit structure of a 3D memory array MSC including the semiconductor structure of the present embodiment will be described.

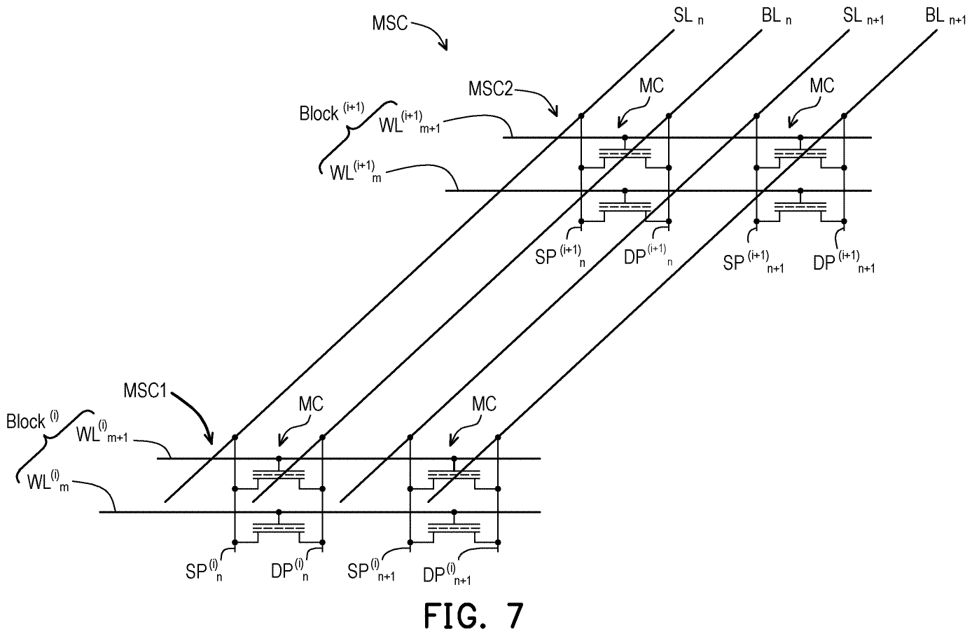

FIG. 7 is a circuit diagram of the 3D AND flash memory array including the semiconductor structure of present invention.

Referring to FIG. 7, two blocks BLOCK⁽ⁱ⁾ and BLOCK⁽ⁱ⁺¹⁾ of a vertical AND memory array MSC are arranged in rows and columns. The block BLOCK⁽ⁱ⁾ includes a memory array MSC1. A row (e.g., an (m+1)^{th} row) of the memory array MSC1 is a set of AND memory cells MC having a common word line (e.g., WL⁽ⁱ⁾ₘ₊₁). The AND memory cells MC of the memory array MSC1 in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP (i) n and DP⁽ⁱ⁾ₙ₊₁), so that the AND memory cells MC are logically arranged in a row along the common word line (e.g., WL⁽ⁱ⁾ₘ₊₁).

A column (e.g., an n^{th} column) of the memory array MSC1 is a set of AND memory cells MC having a common source pillar (e.g., SP⁽ⁱ⁾ₙ) and a common drain pillar (e.g., DP⁽ⁱ⁾ₙ). The AND memory cells MC of the memory array MSC1 in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells MC of the memory array MSC1 are logically arranged in a column along the common source pillar (e.g., SP⁽ⁱ⁾ₙ) and the common drain pillar (e.g., DP⁽ⁱ⁾ₙ). In the physical layout, according to the manufacturing method as applied, the columns or rows may be twisted and arranged in a honeycomb pattern or other patterns for high density or other reasons.

In FIG. 7, in the block BLOCK⁽ⁱ⁾, the AND memory cells MC in the n^{th} column of the memory array MSC1 share a common source pillar (e.g., SP⁽ⁱ⁾ₙ) and a common drain pillar (e.g., DP⁽ⁱ⁾ₙ). The AND memory cells MC in an (n+1)^{th} column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array MSC2, which is similar to the memory array MSC1 in the block BLOCK⁽ⁱ⁾. A row (e.g., an (m+1)^{th} row) of the memory array MSC2 is a set of AND memory cells MC having a common word line (e.g., WL⁽ⁱ⁺¹⁾ₘ₊₁). The AND memory cells MC of the memory array MSC2 in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array MSC2 is a set of AND memory cells MC having a common source pillar (e.g., SP⁽ⁱ⁺¹⁾ₙ) and a common drain pillar (e.g., DP⁽ⁱ⁺¹⁾ₙ). The AND memory cells MC are integrated and connected in parallel, and thus may be also referred to as a memory string. The AND memory cells MC of the memory array MSC2 in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells MC of the memory array MSC2 are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells MC in the AND memory array MSC1 of the block BLOCK⁽ⁱ⁾, and are coupled to the n^{th} column of AND memory cells MC in the AND memory array MSC2 of the block BLOCK⁽ⁱ⁺¹⁾. Similarly, the source line SLₙ₊₁ and the bit line BLₙ₊₁ are coupled to the (n+1)^{th} column of AND memory cells MC in the AND memory array MSC1 of the block BLOCK⁽ⁱ⁾, and are coupled to the (n+1)^{th} column of AND memory cells MC in the AND memory array MSC2 of the block BLOCK⁽ⁱ⁺¹⁾.

It will be apparent to those skilled in the art that various modifications and variations may be made to the disclosed embodiments without departing from the scope or spirit of the invention. In view of the foregoing, it is intended that the invention covers modifications and variations provided that they fall within the scope of the following claims and their equivalents.

What is claimed is:

1. A semiconductor structure for a three-dimensional (3D) memory, comprising:
a substrate, having a memory device region and a peripheral region surrounding the memory device region, wherein the memory device region comprises a memory array region and a staircase region;
a circuit structure layer, disposed on the substrate;
a first conductive layer, disposed on the circuit structure layer;
a stacked structure, disposed on the first conductive layer in the memory device region, comprising a plurality of second conductive layers and a plurality of insulating layers alternately stacked, and having a staircase profile in the staircase region;
an oxide layer, disposed on the first conductive layer and surrounding the stacked structure;
a first insulating wall, disposed in the oxide layer, penetrating through the first conductive layer, and surrounding the stacked structure; and
a plurality of first dummy pillars, disposed in the peripheral region and the staircase region, wherein each first dummy pillar in the peripheral region penetrates through the oxide layer and the first conductive layer, and each first dummy pillar in the staircase region penetrates through the stacked structure and the first conductive layer.

2. The semiconductor structure of claim 1, further comprising a plurality of supporting pillars, disposed in the staircase region, and penetrating through the stacked structure and the first conductive layer.

3. The semiconductor structure of claim 2, further comprising a plurality of second insulating walls parallel to each other, disposed in the stacked structure to divide the stacked structure into a plurality of blocks arranged parallel to each other.

4. The semiconductor structure of claim 3, wherein in each of the blocks, the first dummy pillars are located at a first side of the memory array region, and the supporting pillars are located at a second side opposite to the first side of the memory array region.

5. The semiconductor structure of claim 4, wherein the first dummy pillars in each of the blocks are adjacent to the supporting pillars in an adjacent block, and the supporting pillars in each of the blocks are adjacent to the first dummy pillars in an adjacent block.

6. The semiconductor structure of claim 1, further comprising a plurality of vertical channel structures, disposed in the memory array region and penetrating through the stacked structure and the first conductive layer.

7. The semiconductor structure of claim 1, wherein the first insulating wall is located in the memory device region and adjacent to a boundary between the memory device region and the peripheral region, and spacing a distance from a lowermost second conductive layer in the stacked structure.

8. A manufacturing method of a semiconductor structure for a three-dimensional (3D) memory, comprising:
providing a substrate, wherein the substrate has a memory device region and a peripheral region surrounding the memory device region, and the memory device region comprises a memory array region and a staircase region;
forming a circuit structure layer on the substrate;
forming a first conductive layer on the circuit structure layer;
forming a stacked structure on the first conductive layer in the memory device region, wherein the stacked structure comprises a plurality of second conductive layers and a plurality of insulating layers alternately stacked and has a staircase profile in the staircase region;
forming an oxide layer on the first conductive layer, wherein the oxide layer surrounds the stacked structure;
forming a first insulating wall in the oxide layer, wherein the first insulating wall penetrates through the first conductive layer and surrounds the stacked structure; and
forming a plurality of first dummy pillars in the peripheral region and the staircase region, wherein each first dummy pillar in the peripheral region penetrates through the oxide layer and the first conductive layer, and each first dummy pillar in the staircase region penetrates through the stacked structure and the first conductive layer.

9. The manufacturing method of claim 8, wherein a forming method of the stacked structure and the oxide layer comprises:
forming a first initial stacked structure on the first conductive layer, wherein the first initial stacked structure comprises the plurality of insulating layers and a plurality of sacrificial layers alternately stacked;
removing a part of the insulating layers and a part of the sacrificial layers to expose the first conductive layer in the peripheral region and to form a second initial stacked structure in the memory device region, wherein the second initial stacked structure has the staircase profile in the staircase region;
forming the oxide layer on the first conductive layer; and
replacing the plurality of sacrificial layers with the plurality of second conductive layers.

10. The manufacturing method of claim 9, wherein after forming the oxide layer and before replacing the plurality of sacrificial layers with the plurality of second conductive layers, further comprising:
forming a plurality of vertical channel structures in the memory array region, wherein each vertical channel structure penetrates through the second initial stacked structure and the first conductive layer.

11. The manufacturing method of claim 10, wherein after forming the plurality of vertical channel structures and before replacing the plurality of sacrificial layers with the plurality of second conductive layers, further comprising:
forming the plurality of first dummy pillars in the peripheral region and the staircase region, wherein each first dummy pillar in the peripheral region penetrates through the first conductive layer, and each first dummy pillar in the staircase region penetrates the oxide layer and the second initial stacked structure and the first conductive layer.

12. The manufacturing method of claim 11, wherein when forming the plurality of vertical channel structures, further comprising:
forming a plurality of supporting pillars in the staircase region, wherein each supporting pillar penetrates through the second initial stacked structure and the first conductive layer.

13. The manufacturing method of claim 12, wherein after forming the plurality of first dummy pillars, further comprising:
forming a first slit in the oxide layer, wherein the first slit penetrates through the oxide layer and the first conductive layer and surrounds the second initial stacked structure;
forming a plurality of second slits parallel to each other in the second initial stacked structure to divide the second initial stacked structure into a plurality of blocks arranged parallel to each other;
replacing the plurality of sacrificial layers with the plurality of second conductive layers; and
filling the first slit and the plurality of second slits with an insulating material to form the first insulating wall in the first slit and a plurality of second insulating walls in the second slits.

14. The manufacturing method of claim 9, wherein after forming the oxide layer and before replacing the plurality of sacrificial layers with the plurality of second conductive layers, further comprising:
forming the plurality of first dummy pillars in the peripheral region and the staircase region, wherein each first dummy pillar in the staircase region penetrates through the second initial stacked structure and the first conductive layer.

15. The manufacturing method of claim 14, wherein after forming the plurality of first dummy pillars and before replacing the plurality of sacrificial layers with the plurality of second conductive layers, further comprising:
forming a plurality of vertical channel structures in the memory array region, wherein each vertical channel structure penetrates through the second initial stacked structure and the first conductive layer.

16. The manufacturing method of claim 15, wherein when forming the plurality of vertical channel structures, further comprising:
forming a plurality of supporting pillars in the staircase region, wherein each supporting pillar penetrates through the second initial stacked structure and the first conductive layer.

17. The manufacturing method of claim 15, wherein after forming the plurality of vertical channel structures, further comprising:
forming a first slit in the oxide layer, wherein the first slit penetrates through the first conductive layer and surrounds the second initial stacked structure;
forming a plurality of second slits parallel to each other in the second initial stacked structure to divide the second initial stacked structure into a plurality of blocks arranged parallel to each other;
replacing the plurality of sacrificial layers with the plurality of second conductive layers; and
filling the first slit and the plurality of second slits with an insulating material to form the first insulating wall in the first slit and a plurality of second insulating walls in the second slits.

18. The manufacturing method of claim 8, wherein before forming the plurality of first dummy pillars, further comprising:
forming a plurality of vertical channel structures in the memory array region, wherein each vertical channel structure penetrates through the second initial stacked structure and the first conductive layer.

19. The manufacturing method of claim 18, wherein when forming the plurality of vertical channel structures, further comprising:
forming a plurality of supporting pillars in the staircase region, wherein each supporting pillar penetrates through the second initial stacked structure and the first conductive layer.

20. The manufacturing method of claim 8, wherein the first insulating wall is located in the memory device region and adjacent to a boundary between the memory device region and the peripheral region, and spacing a distance from a lowermost second conductive layer in the stacked structure.
